(19) United States
(12) Patent Application Publication
(10) Pub. No.: US 2010/0092662 A1
(43) Pub. Date: Apr. 15, 2010

(54) Rough Bonding Agent Layers by Means of HS-PVD or Cold Spray

(75) Inventors: Knut Halberstadt, Mulheim an der Ruhr (DE); Werner Stamm, Mulheim an der Ruhr (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: SIEMENS AKTIENGESELLSCHAFT, Muenchen (DE)

(21) Appl. No.: 12/514,601

(22) PCT Filed: Aug. 15, 2007
(86) PCT No.: PCT/EP2007/058427

§ 371 Date: Dec. 23, 2009

(30) Foreign Application Priority Data
Nov. 14, 2006 (EP) 06023663.5

(51) Int. Cl. B05D 1/38; B05C 5/00; B05B 7/14; C23C 14/46

(52) U.S. Cl. 427/185; 118/310; 204/298.04

(57) ABSTRACT

An HS-PVD (high speed physical vapor deposition) or cold spray method for coating a substrate with a bonding agent layer is provided. This method includes generating a particle stream of a coating material, depositing the particle stream on the substrate and subjecting the substrate to a subsequent thermal treatment, wherein powder particles with a larger particle size are added to the particle stream. A device for implementing the method is also provided.

### CROSS REFERENCE TO RELATED APPLICATIONS

This application is the US National Stage of International Application No. PCT/EP2007/058427 filed Aug. 15, 2007 and claims the benefit thereof. The International Application claims the benefits of European Patent Office application No. 06023663.5 EP filed Nov. 14, 2006, both of the applications are incorporated by reference herein in their entirety.

### FIELD OF INVENTION

The invention relates to an HS-PVD or cold spray method for coating a substrate with a bonding agent layer, in which a particle stream of a coating material is generated, deposited on the substrate and subjected to a subsequent heat treatment. The invention furthermore relates to a device for carrying out the method.

### BACKGROUND OF INVENTION

In the prior art, it is known to provide substrates such as turbine blades with a bonding agent layer, for example of MCrAlY, with the aid of an HS-PVD method (high speed physical vapor deposition). To this end, an MCrAlY vapor cloud is generated from an MCrAlY ingot by means of an accelerated argon ion stream. Using electric and magnetic fields, this vapor is delivered through a gap and accelerated in the direction of the substrate to be coated, to which an electric field is also applied, on which it is deposited. The applied MCrAlY layer is then subjected to a heat treatment.

It is also known to apply an MCrAlY bonding agent layer onto a turbine blade by a cold spray method. In this case, an MCrAlY powder with a grain size of about 22 μm-45 μm in a gas stream is heated to a temperature of up to 600° C. by means of a preheating unit and provided with the required kinetic energy by subsequent acceleration to a speed of up to Mach 3. The particle stream formed in this way is deposited on the substrate and then likewise subjected to a heat treatment.

### SUMMARY OF INVENTION

Both known methods provide a smooth, homogeneous MCrAlY coating which is unsuitable for coating with a thermal barrier layer, for example an APS-TBC. This is due in particular to the fact that the adhesion of the thermal barrier layer on the bonding agent layer is insufficient.

It is therefore an object of the present invention to refine a method of the type mentioned in the introduction so that a rough bonding agent layer, which ensures better adhesion of the thermal barrier layer, can be applied on the substrate.

In a method of the type mentioned in the introduction, this object is achieved by adding powder grains with a larger grain size to the particle stream.

The basic concept of the invention is thus to add powder grains, the grain size of which is greater than the grain size of the particles, to the particle stream of the coating material which is generated by an HS-PVD method or by a cold spray method. The mixed particle stream modified in this way is then deposited on the component, so as to obtain a coating which contains at least particles or grains with two different grain sizes. This layer may also be designed as a duplex layer, with the coarse grain size only been added to the upper layer. After the subsequent heat treatment, a bonding agent layer is obtained which has a rough surface owing to the different grain sizes of the particles or grains which it contains. These surface properties ensure secure bonding of a thermal barrier layer which may be applied later.

According to a first embodiment of the invention, MCrAlY is used as the coating material. This material is particularly suitable since it ensures good adhesion on different substrates and also forms a chemically and physically stable base for various thermal barrier layers.

Powder grains of the coating material may also be added to the particle stream. In this way, a bonding agent layer with a homogeneous material composition is obtained. As an alternative or in addition, it is also possible for powder grains which do not consist of the coating material to be added to the particle stream.

The grain size of the powder grains may be between 45 μm and 85 μm. In this case, a bonding agent layer is obtained in which the powder grains are embedded in a matrix of finer particles, so that a high degree of roughness is obtained.

According to another embodiment of the invention, the powder grains are accelerated to a speed in the vicinity of the speed of sound and then added to the particle stream. This ensures that the powder grains are fully incorporated into the bonding agent layer, since it avoids parts of the powder grains being reflected elastically from the surface of the substrate owing to an excessive speed.

It may be expedient to heat the powder grains before they are added to the particle stream, in order to prevent the temperature level of the particle stream being reduced by the addition of powder grains. In this case, the temperature should lie particularly in the range of between 550° C. and 650° C.

As the substrate, a turbine blade may be coated with the bonding agent layer. An advantage in this case is that the bonding agent layer obtained satisfies the stringent requirements during operation of the turbine particularly well, and ensures strong bonding of a thermal barrier layer which may be applied on it.

The object is also achieved by a device for carrying out the method according to the invention.

### BRIEF DESCRIPTION OF THE DRAWINGS

The invention will be explained in more detail below with the aid of two exemplary embodiments, with reference to the appended drawings.

In the drawings,

FIG. 1 shows a schematic representation of a first device according to the invention, and

FIG. 2 shows a schematic representation of a second device according to the invention.

### DETAILED DESCRIPTION OF INVENTION

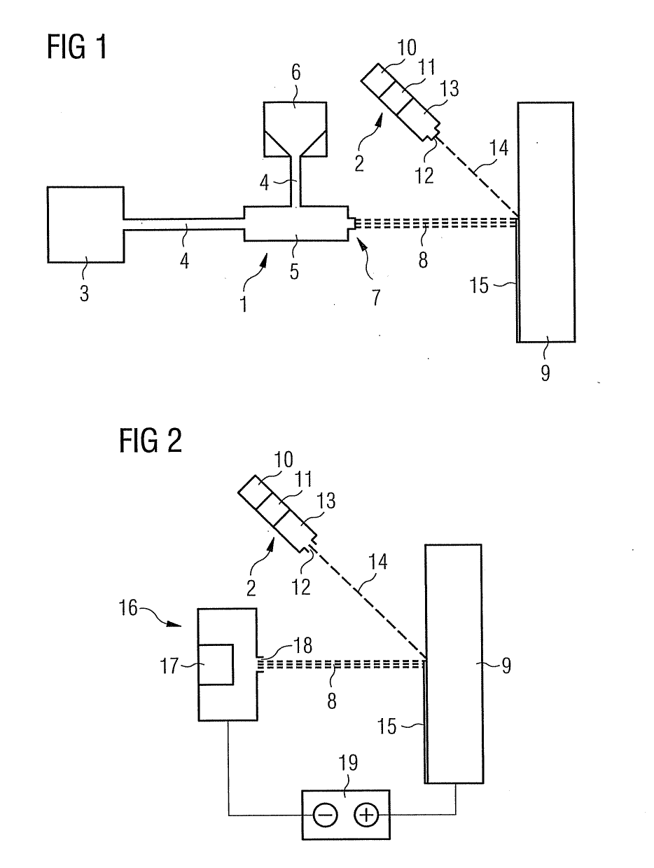

FIG. 1 represents a first device according to the invention for carrying out the method according to the invention. The device comprises a cold spray apparatus 1 and a feed apparatus 2 for powder grains. The cold spray apparatus has a gas feed apparatus 3, which is also provided with a heating apparatus (not shown) for heating the gas. The gas feed apparatus 3 is connected via a line 4 to a spray apparatus 5. The spray apparatus 5 is furthermore connected via a line 2 to a powder reservoir 6, which contains powder particles of an MCrAlY coating material with a grain size of from 15 to 30 μm. The spray apparatus 5 furthermore has an output nozzle 7, from which a particle stream 8 is delivered in the direction of the turbine blade 9 to be coated.

The feed apparatus 2 contains a reservoir 10, which holds MCrAlY powder grains with a grain size of between 45 and 85 μm, as well as a preheating unit 11 for preheating the powder grains, and lastly an accelerating unit 13 arranged immediately before an output opening 12 in order to accelerate the powder grains.

A stream of powder grains 14 emerges from the output opening 12 and strikes the surface of the turbine blade 9 simultaneously with the particle stream 8.

In order to coat the turbine blade 9 with an MCrAlY bonding agent layer using the device according to the invention, a gas is provided in the gas feed apparatus 3 and heated to a temperature of up to 600° C. This gas flows through the line 4 into the spray apparatus 5, in which particles coming from the powder reservoir 6 are injected into the gas stream.

The resulting gas/particle mixture is then accelerated in the spray apparatus 5 to a speed of up to Mach 3 and delivered through the output nozzle 7 in the direction of the turbine blade 9, the surface of which it finally strikes. The MCrAlY particles are thereby cold-welded to the substrate and to one another owing to their high kinetic energy.

At the same time, the powder grains from the reservoir 10 are delivered in the feed apparatus 2 to the preheating unit 11, and heated in the latter to a temperature of about 600° C. From the preheating unit 11, the powder grains enter the accelerating unit 13 where they are accelerated to a speed in the vicinity of the speed of sound and subsequently delivered through the exit opening 12 in the direction of the turbine blade 9.

The stream of powder grains 14 created in this way strikes the surface of the turbine blade 9 simultaneously with the particle stream 8, while being mixed with it. As a result, a mixed jet is deposited.

The coating 15 formed on the surface of the turbine blade 9 contains both powder particles with a grain size of from 15 μm to 30 μm, and powder grains with a grain size of between 45 μm and 85 μm.

After the coating 15 has been applied onto the turbine blade 9, the latter is subjected to a subsequent heat treatment with the aid of a heating apparatus (not shown), during which the powder grains react with the substrate by diffusion so as to form a firmly adhering rough bonding agent layer.

FIG. 2 shows a second device according to the invention for coating a substrate with a bonding agent layer. The device comprises an HS-PVD apparatus 16 and a powder grain feed apparatus 2.

The HS-PVD apparatus 16 has an exit plate 18 and an ion source 17 which contains a cathode (not shown) made of an MCrAlY ingot, from which an MCrAlY ion vapor cloud is generated by means of an argon ion stream (also not shown).

An electric field is applied with the aid of the current source 19 to the exit gap 18 of the HS-PVD apparatus 16 and to the turbine blade 9. This electric field collimates the MCrAlY ions through the exit gap 18 and delivers them in the direction of the turbine blade 9 as a focused particle beam 8. The latter strikes the surface of the turbine blade 9 and is deposited there.

The feed apparatus 2 is identical to the feed apparatus 2 described in FIG. 1.

In order to coat the turbine blade 9 using the second device according to the invention, MCrAlY ions are generated in the ion source 17 of the HS-PVD apparatus 16, and these are collimated with the aid of the applied electric field through the exit gap 18 to form the particle stream 8 and delivered in the direction of the turbine blade 9.

At the same time, powder grains whose grain size lies between 45 μm and 85 μm are heated, accelerated, and delivered in the direction of the turbine blade 9 by the feed apparatus 2 in the manner described above.

In the manner already described above, these powder grains strike the surface of the turbine blade 9 simultaneously with the particle stream 8 and form a coating 15 together with it.

The bonding agent layer is formed in its final configuration by a subsequent heat treatment.

Owing to their roughness, the two bonding agent layers described above are highly suitable for ensuring strong adhesion of a thermal barrier layer applied on them.

1.-10. (canceled)

11. A high speed physical vapor deposition or cold spray method for coating a substrate with a bonding agent layer, comprising:
depositing a particle stream from a first apparatus onto the substrate, the particle stream comprising a plurality of first powder grains of a coating material;
subsequently subjecting the substrate to a heat treatment; and
adding to the particle stream a plurality of second powder grains with a larger particle size than the plurality of first powder grains, the plurality of second powder grains added from a second apparatus.

12. The method as claimed in claim 11, wherein a MCrAlY material is used as the coating material.

13. The method as claimed in claim 11,
wherein the plurality of second powder grains are a plurality of particle grains of the coating material, and
wherein the plurality of second particle grains are added to the particle stream during the deposition.

14. The method as claimed in claim 11, wherein the plurality of second powder grains having a particle size between 45 μm and 85 μm are added to the particle stream.

15. The method as darned in claim 11, wherein the plurality of second powder grains are accelerated to a speed that is essentially the speed of sound and then added to the particle stream.

16. The method as claimed in claim 11, wherein the plurality of second powder grains are heated to a temperature in the range of between 550° C. and 650° C. before the plurality of second powder grains are added to the particle stream.

17. The method as claimed in claim 11, wherein a turbine blade is used as the substrate and is coated with the bonding agent layer.

18. The method as claimed in claim 11, wherein the plurality of second powder grains are deposited simultaneously with the particle stream onto the substrate.

19. A first device for coating a substrate with a bonding agent layer, comprising:
a cold spray or a high speed physical vapor deposition apparatus for generating a particle stream comprising a plurality of first powder grains of a coating material and depositing it on the substrate;
a heating apparatus for a heat treatment of a deposited coating material; and
a feed apparatus for injecting a plurality of second powder grains into the particle stream.

20. The first device as claimed in claim 19, wherein the feed apparatus comprises a preheating unit for preheating the plurality of second powder grains.

21. The first device as claimed in claim 20, the feed apparatus further comprises an accelerating unit for accelerating the plurality of second powder grains.

22. The first device as claimed in claim 19, wherein a MCrAlY material is used as the coating material.

23. The first device as claimed in claim 19,
wherein the plurality of second powder grains are a plurality of particle grains of the coating material, and
wherein the plurality of second particle grains are added to the particle stream.

24. The first device as claimed in claim 19, wherein the plurality of second powder grains having a particle size between 45 μm and 85 μm are added to the particle stream.

25. The first device as clamed in claim 19, wherein the plurality of second powder grains are accelerated to a speed that is essentially the speed of sound and then added to the particle stream.

26. The first device as claimed in claim 19, wherein the plurality of second powder grains are heated to a temperature in the range of between 550° C. and 650° C. before the plurality of second powder grains are added to the particle stream.

27. The first device as claimed in claim 19, wherein a turbine blade is used as the substrate and is coated with the bonding agent layer.

28. A second device for coating a substrate with a bonding agent layer, comprising:
a high speed physical vapor deposition apparatus, the high speed physical vapor deposition apparatus comprising:
an exit plate, and
an ion source wherein the ion source includes a cathode made of a MCrAlY ingot generating a MCrAlY ion vapor cloud; and
a feed apparatus for injecting a plurality of powder grains into the particle stream,
wherein an electric field is applied by a current source to the exit plate and to a turbine blade.

29. The second device as claimed in claim 28, wherein the plurality of powder grains having a particle size between 45 μm and 85 μm are added to the particle stream.

30. The second device as claimed in claim 28, wherein the electric field collimates the MCrAlY ions through the exit plate and delivers them in a direction of the turbine blade as a focused particle beam.
